(19) United States
(12) Patent Application Publication
(10) Pub. No.: US 2013/0099327 A1
(43) Pub. Date: Apr. 25, 2013

(54) CMOS DEVICES AND METHOD FOR MANUFACTURING THE SAME

(71) Applicants: Hsiaochia Wu, Wuxi (CN); Li Guo, Wuxi (CN); Guangtao Han, Wuxi (CN); Jian Yan, Wuxi (CN)

(72) Inventors: Hsiaochia Wu, Wuxi (CN); Li Guo, Wuxi (CN); Guangtao Han, Wuxi (CN); Jian Yan, Wuxi (CN)

(21) Appl. No.: 13/807,309

(22) PCT Filed: Nov. 30, 2011
(86) PCT No.: PCT/CN11/83240

§ 371 Date: Dec. 28, 2012

(30) Foreign Application Priority Data
Dec. 16, 2010 (CN) 201010593032.9

(51) Int. Cl. H01L 21/265; H01L 29/78

(52) U.S. Cl. CPC H01L 21/265; H01L 29/7833
USPC 257/408; 438/514

(57) ABSTRACT

A complementary metal-oxide semiconductor (CMOS) device is disclosed. The CMOS device includes a substrate, a well region formed in the substrate, and a gate formed on the substrate. The CMOS device also includes a first region and a second region formed in the well region and arranged at two sides of the gate. Further, the CMOS device includes a first light-doped drain (LDD) region and a second LDD region formed in the well region and extending the first region and the second region, respectively, towards the gate. The CMOS device also includes a first doped layer formed in the first LDD region, and a conduction type of an ion doped in the first doped layer is opposite to a conduction type of an ion doped in the first LDD region.

### FIELD OF THE INVENTION

The present invention generally relates to the field of semiconductor manufacturing and, more particularly, to the complementary metal-oxide semiconductor (CMOS) technologies.

### BACKGROUND

Complementary metal-oxide semiconductor (CMOS) devices are basic units used in large scale integrated circuits (LSI). In order to increase the degree of integration of the integrated circuits, the line width of the CMOS devices needs be correspondingly reduced. However, in practical applications, further reduction of operating voltages of the CMOS devices is limited, thus the internal electric field strength of the CMOS devices increases. The increase in the internal electric field strength can lead to increased hot-carrier effect, and reduces the breakdown voltages of the CMOS devices.

A conventional solution introduces into a drain region of a CMOS device a light-doped drain (LDD) region having the same doping type as the drain region. When the CMOS device works in a forward mode, the V_{DS} is mainly applied in the LDD region and the depletion region width is mainly provided by the LDD region. In this way, the short channel effect due to channel charge sharing is improved, and the breakdown voltage of the CMOS device is improved. Therefore, the introduction of the LDD region improves the performance of the CMOS device.

However, the introduction of the LDD region may increase the resistance of the CMOS device and decrease the on-state current. The LDD region at low concentration may lead to an increase in leakage resistance, and further result in the loss of the current. To achieve a high on-state current, the conventional solution may increase the dose of ion implantation in the LDD region. But the increased dose of ion implantation in the LDD region may narrow the depletion region width in the LDD region, and the CMOS device having a narrower depletion region may have an electric field with an increased peak under a same load voltage. The existence of a large electric field reduces the breakdown voltage of the CMOS device, and reduces the device's ability to resist the hot carrier effect. Therefore, with the conventional solution, the on-state current and breakdown voltage cannot be improved at the same time, i.e., improving one aspect may lead to worsening of the other aspect.

The disclosed methods and systems are directed to solve one or more problems set forth above and other problems.

### BRIEF SUMMARY OF THE DISCLOSURE

One aspect of the present disclosure includes a complementary metal-oxide semiconductor (CMOS) device. The CMOS device includes a substrate, a well region formed in the substrate, and a gate formed on the substrate. The CMOS device also includes a first region and a second region formed in the well region and arranged at two sides of the gate. Further, the CMOS device includes a first light-doped drain (LDD) region and a second LDD region formed in the well region and extending the first region and the second region, respectively, towards the gate. The CMOS device also includes a first doped layer formed in the first LDD region, and a conduction type of an ion doped in the first doped layer is opposite to a conduction type of an ion doped in the first LDD region.

Another aspect of the present disclosure includes a fabrication process integrated into a manufacturing method of a CMOS device to make a doped layer after forming a light-doped drain (LDD) region. The fabrication process includes selecting a conduction type of an ion doped in the doped layer as opposite to a conduction type of an ion doped in the LDD region and selecting a particular ion of the conduction type based on a type of the CMOS device. The fabrication process also includes forming the doped layer in the LDD region by an ion implantation process using the particular ion of the conduction type at a controlled ion concentration.

Other aspects of the present disclosure can be understood by those skilled in the art in light of the description, the claims, and the drawings of the present disclosure.

### BRIEF DESCRIPTION OF THE DRAWINGS

FIG. 1 illustrates an exemplary CMOS device consistent with the disclosed embodiments;

FIG. 2 illustrates another exemplary CMOS device consistent with the disclosed embodiments; and

FIG. 3 illustrates another exemplary CMOS device consistent with the disclosed embodiments.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

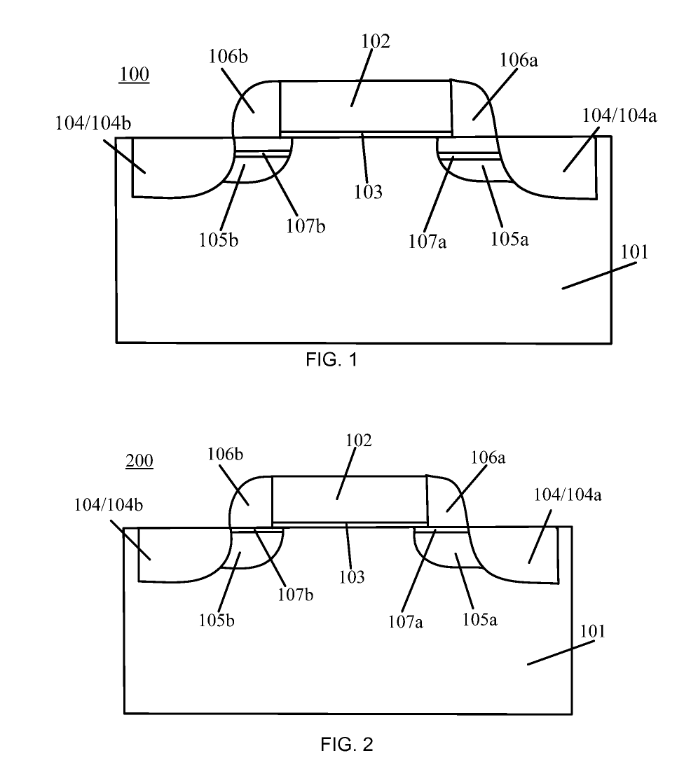

FIG. 1 shows an exemplary complementary metal-oxide semiconductor (CMOS) device 100 consistent with the disclosed embodiment. As shown in FIG. 1, CMOS device 100 includes a substrate (not shown) and a well region 101 formed in the substrate. Further, CMOS device 100 includes a polysilicon gate 102, a gate oxide 103, a source and drain region 104, a first light-doped drain (LDD) region 105a, a second LDD region 105b, a first offset spacer 106a, and a second offset spacer 106b. Other structures may also be included and certain structures may be omitted.

The substrate may include any appropriate material for making CMOS devices. For example, the substrate may include a semiconductor structure, e.g., silicon, silicon germanium (SiGe) with a monocrystalline, polycrystalline, or amorphous structure. The substrate may also include a hybrid semiconductor structure, e.g., carborundum, indium antimonide, lead telluride, indium arsenide, indium phosphide, gallium arsenide or gallium antimonide, alloy semiconductor, or a combination thereof. Further, the substrate may include a silicon-on-insulator (SOI) structure. In addition, the substrate may also include other materials, such as a multi-layered structure of epitaxial layer or buried layer. Other materials may also be used.

The source and drain region 104 may include a first region 104a (e.g., drain region) and a second region 104b (e.g., source region). Both the first region 104a and the second region 104b are formed in the well region 101. Spacers 106a and 106b may be formed at two sides of gate 102 for spacing and protection. Further, the first LDD region 105a and the second LDD region 105b are formed along the first region 104a and the second region 104b, respectively, and extend the first region 104a and the second region 104b towards the gate 102.

Further, the first LDD region 105a includes a first doped layer 107a, and the second LDD region 105b includes a second doped layer 107b. The first dope layer 107a and the second LDD region 105b may be formed in the corresponding LDD regions by doping a certain layer of a respective LDD region. The conduction type of the ion doped in the doped layer 107a or 107b may be opposite to the doping type in the LDD region 105a or 105b.

The CMOS device 100 may be a P-type MOS (PMOS) device or an N-type MOS (NMOS) device. In certain embodiments, the CMOS device 100 may be an NMOS device. The well region 101 may then be P-type doped, and the first LDD region 105a and the second LDD region 105b may be N-type doping. Thus, the first doped layer 107a and the second doped layer 107b may be P-type doped.

More specifically, the conductive particles/ions doped in the first LDD region 105a and/or the second LDD region 105b may be phosphorus, and the conductive particles/ions doped in the first doped layer 107a and/or the second doped layer 107b may be indium. Further, the first LDD region 105a and/or the second LDD region 105b may be implanted with a certain dose of indium ions using D-RESURF (double reduced surface field) technology, so that a concentration of the P-type doped layer formed in the corresponding LDD region may be higher than the doping concentration of the first LDD region 105a and/or the second LDD region 105b is.

After forming the first doped layer 107a, there are a transverse PN junction and a longitudinal PN junction between the first LDD region 105a and the well area 101, and there is another longitudinal PN junction between the first LDD region 105a and the first doped layer 107a. That is, there are a transverse PN junction and two longitudinal PN junctions around the first LDD region 105a. An additional PN junction is formed by introducing the first doped layer 107a.

Similarly, after forming the second doped layer 107b, there are a transverse PN junction and a longitudinal PN junction between the second LDD region 105b and the well area 101, and there is another longitudinal PN junction between the second LDD region 105b and the second doped layer 107b. That is, there are a transverse PN junction and two longitudinal PN junctions around the second LDD region 105b.

When a forward voltage is imposed on a drain electrode of the CMOS device 100, the three PN junctions around the first LDD region 105a are all in reverse biased mode. The space charge region extends to the first LDD region 105a, and be superposed in the first LDD region 105a, to make the first LDD region 105a more easily be totally depleted. Therefore, the breakdown voltage of the CMOS device 100 is improved.

Compared with conventional NMOS CMOS devices, because the CMOS device 100 has the P-type doped layer 107a, the LDD region 105a can have a doped concentration higher than the conventional LDD region. As a result of the additional doped layer(s), the LDD region having a high doping concentration may be depleted as well, so that the breakdown voltage is not affected. That is, the doped layer 107a may add an additional PN junction between the doped layer and the LDD region to enable the LDD region to be depleted even when doping concentration in the LDD region increases. In addition, the LDD region having high doping concentration may decrease the on-state resistance and increase the on-state current. In other words, the first doped layer 107a is arranged to deplete the first LDD region 105a cooperating with the substrate, and to make the first LDD region 105a more easily to be totally depleted.

The doped layer 107a or 107b may be formed in any part of the LDD region 105a or 105b. More specifically, the doped layer 107a or 107b may be formed on the surface, in the middle portion, or at the bottom of the LDD region 105a or 105b.

FIG. 2 shows an exemplary CMOS device 200 with a different LDD region configuration. As shown in FIG. 2, similar to CMOS device 100, CMOS device 200 also include the substrate (not shown) and well region 101, polysilicon gate 102, gate oxide 103, source and drain region 104 (e.g., first region 104a and second region 104b), first LDD region 105a, second LDD region 105b, first offset spacer 106a, and second offset spacer 106b. However, first doped layer 107a is arranged on the surface of first LDD region 105a and in the well region 101, and second doped layer 107b is arranged on the surface of second LDD region 105b and in the well region 101.

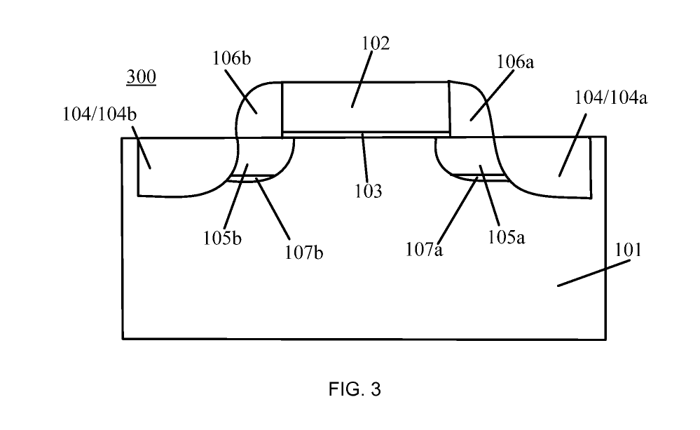

FIG. 3 shows an exemplary CMOS device 300 with another different LDD region configuration. As shown in FIG. 3, similar to CMOS device 100, CMOS device 300 also include the substrate (not shown) and well region 101, polysilicon gate 102, gate oxide 103, source and drain region 104 (e.g., first region 104a and second region 104b), first LDD region 105a, second LDD region 105b, first offset spacer 106a, and second offset spacer 106b. However, first doped layer 107a is arranged at the bottom of first LDD region 105a, and second doped layer 107b is arranged at the bottom of second LDD region 105b. Other configurations may also be used. For example, each of the first doped layer 107a and second doped layer 107b may be arranged independently using any one of the three configurations of surface, middle, and bottom of the corresponding LDD region.

When the dose implanted in the LDD region 105a and/or 105b increases, the doped layer 107a and/or 107b can increase the depletion speed in the LDD region 105a and/or 105b cooperating with the substrate to make the CMOS device totally depleted. In this way, the breakdown voltage of the CMOS device can remain unchanged. At the same time, because of the improvement of ion concentration in LDD region, the on-state resistance of the CMOS device is decreased. Thus, the on-state current of the CMOS device is improved. Therefore, the doped layer 107a and/or 107b may be a doped layer with a high doped concentration. Specifically, the concentration of the doped layer may be in the range from about 1016 cm⁻³ to about 1019 cm⁻³.

For example, in an NMOS device, if the current of the device is increased by increasing the dose of the ion implanted into the LDD region without adding the P-type doped layer 107a and/or 107b, it may be difficult for the LDD region to be depleted. Thus, the breakdown voltage may decrease and the hot-carrier effect may be aggravated. On the other hand, if a high concentration P-type doped layer is implanted to the LDD region, the depletion of the LDD region is enhanced by the longitudinal PN junction formed by the P-type doped layer and the LDD region. Therefore, even when the concentration of the LDD region increases, the LDD region can be totally depleted. That is, as the drive current of the device increases, the breakdown voltage remains unchanged, and the hot-carrier effect is not increased.

In certain embodiments, the doped layer 107a and/or 107b may be formed in the LDD region using an ion implantation process. To control the concentration and the depth of the ion implanted to the doped layer 107a and/or 107b, the diffusion coefficient of the ion doped in the doped layer may be determined based on particular applications, and may be less than, more than, or equal to the diffusion coefficient of the ion doped in the LDD region.

For example, in certain embodiments, a shallow doped layer may be formed and the diffusion coefficient of the ion doped in the doped layer may be less than the diffusion coefficient of the ion doped in the LDD region. Take NMOS for example, the ion doped in the LDD region may be phosphorus or other ions, and the ion doped in the doped layer may be indium or other ions. Further, the ion implantation process of the LDD region and the doped layer 107a and/or 107b may use the same mask. Because the diffusion coefficient of indium is significantly less than the diffusion coefficient of phosphorus, a substantially shallow doped layer 107a and/or 107b may be formed in the LDD region. Thus, the doped ion concentration in most of the LDD region is not affected by forming the doped layer 107a and/or 107b.

PMOS devices may also be similarly used. PMOS and NMOS may have the same structure, with the corresponding regions having opposite type of conductive ions. More specifically, the PMOS is P-type doping in the LDD region, and N-type doping in the doped layer 107a and/or 107b. However, as the PMOS and NMOS devices have similar structures, similar effects may be achieved and detailed descriptions are omitted.

In addition, corresponding to the above mentioned CMOS devices, a process to fabricate the doped layer may be added to the manufacturing process making the CMOS device such that the doped layer can be made in the existing manufacturing process. For example, after forming an LDD region, a doped layer is formed in the LDD region by an ion implantation process. To form the doped layer, a conduct type of the doping ion may be first selected. For example, the conduction type of the ion doped in the doped layer may be selected as one opposite to the ion doped in the LDD region. The ion may also be selected. For example, in NMOS devices, the LDD region is N type doping, and the doped layer is P type doping. The ion doped in the LDD region may be phosphorus or other ions, and the ion doped in the doped layer may be selected as indium or other ions. In PMOS devices, the LDD region is P type doping, and the doped layer is N-type doped.

Further, the ion implantation concentration and the ion implantation depth of the doped layer may be controlled when forming the doped layer. An ion implantation layer may be first formed on the surface of the LDD region. Using the ion implantation layer, the ion implantation concentration and the ion implantation depth of the doped layer may be controlled and the doped layer may be made at various locations such as on the surface, in the middle portion, or at the bottom of the LDD region, and to make the ion concentration of the doped layer in a desired range, for example, at about 1016 cm⁻³ to about 1019 cm⁻³. PMOS devices can also be used.

To control the concentration and the depth of the ion implanted to the doped layer, the diffusion coefficient of the ion doped in the doped layer may also be determined. Based on particular applications, the diffusion coefficient of the ion doped in the doped layer may controlled to be less than, more than, or equal to the diffusion coefficient of the ion doped in the LDD region. For example, to form a shallow doped layer, the diffusion coefficient of the ion doped in the doped layer is determined to be less than the diffusion coefficient of the ion doped in the LDD region. In addition, the LDD region and the doped layer may use the same mask as the mask in the ion implantation process.

By using the disclosed systems/devices and methods, a doped layer is formed in the LDD region of a CMOS device, and the conduction type of the ion doped in the doped layer is opposite to that in the LDD region. Therefore, when a forward voltage is applied on the drain electrode of the CMOS device, the doped layer and the LDD region can form a longitudinal reversed biased PN junction, and then the doped layer can increase the depletion speed in the LDD region cooperating with the substrate to make the CMOS device totally depleted. In this way, the breakdown voltage of the CMOS device may remain unchanged and, because of the improvement of ion concentration in LDD region, the on-state resistance of the CMOS device is decreased. As a result, the on-state current of the CMOS device is improved. In addition, the existing manufacturing process of the CMOS device can be added with an ion implantation process for adding the doped layer. The ion implantation process may be fully compatible with the existing manufacturing process of the CMOS devices and, thus, is easy to implement, with low cost, and convenient for large-scale applications.

It is understood that the disclosed embodiments may be applied to any appropriate semiconductor device manufacturing processes and can also be extended to the manufacturing of other MOSFET structures. Various alternations, modifications, or equivalents to the technical solutions of the disclosed embodiments can be obvious to those skilled in the art.

What is claimed is:

1. A complementary metal-oxide semiconductor (CMOS) device, comprising:
a substrate;
a well region formed in the substrate;
a gate formed on the substrate;
a first region and a second region formed in the well region and arranged at two sides of the gate;
a first light-doped drain (LDD) region and a second LDD region formed in the well region and extending the first region and the second region, respectively, towards the gate; and
a first doped layer formed in the first LDD region,
wherein a conduction type of an ion doped in the first doped layer is opposite to a conduction type of an ion doped in the first LDD region.

2. The CMOS device according to claim 1, further including:
a second doped layer formed in the second LDD region, wherein a conduction type of an ion doped in the second doped layer is opposite to a conduction type of an ion doped in the second LDD region.

3. The CMOS device according to claim 1, wherein:
the first doped layer is configured to add an additional PN junction between the first doped layer and the first LDD region to enable the first LDD region to be depleted when doping concentration in the first LDD region increases.

4. The CMOS device according to claim 1, wherein:
the first doped layer is arranged on a surface of the first LDD region.

5. The CMOS device according to claim 1, wherein:
the first doped layer is arranged in a middle portion of the first LDD region.

6. The CMOS device according to claim 1, wherein:
the first doped layer is arranged at a bottom of the first LDD region.

7. The CMOS device according to claim 1, wherein:
the first doped layer is a shallow doped layer, and doped ion concentration of the doped layer is in the range of about 1016 cm⁻³ to 1019 cm⁻³.

8. The CMOS device according to claim 1, wherein:
the first LDD region is doped with phosphorus ions; and
the first doped layer is doped with indium ions.

9. The CMOS device according to claim 8, wherein:
a diffusion coefficient of the doping ions in the first doped layer is less than a diffusion coefficient of the doping ions in the first LDD region.

10. A fabrication process integrated into a manufacturing method of a CMOS device to make a doped layer after forming a light-doped drain (LDD) region, comprising:
selecting a conduction type of an ion doped in the doped layer as opposite to a conduction type of an ion doped in the LDD region;
selecting a particular ion of the conduction type based on a type of the CMOS device;
forming the doped layer in the LDD region by an ion implantation process using the particular ion of the conduction type at a controlled ion concentration.

11. The fabrication process according to claim 10, wherein:
the ion concentration and depth of the doped layer is controlled by forming an ion implantation layer on the surface of the LDD region.

12. The fabrication process according to claim 10, wherein:
the ion implantation process forming the doped layer uses a same mask applied in an ion implantation of the LDD region.

13. The fabrication process according to claim 10, wherein:
the doped layer is formed on a surface of the LDD region.

14. The fabrication process according to claim 10, wherein:
the doped layer is formed in a middle portion of the LDD region.

15. The fabrication process according to claim 10, wherein:
the doped layer is formed at a bottom of the LDD region.
